(19) United States
(12) Patent Application Publication
(10) Pub. No.: US 2025/0199068 A1
(43) Pub. Date: Jun. 19, 2025

(54) APPARATUS, SYSTEM, AND METHOD FOR DISTRIBUTING DIE-SPECIFIC SIGNALS ACROSS DIE STACKS

(71) Applicant: Advanced Micro Devices, Inc., Santa Clara, CA (US)

(72) Inventors: Russell Schreiber, Austin, TX (US); John Wuu, Ft. Collins, CO (US); Shravan Lakshman, Austin, TX (US); James Wingfield, Austin, TX (US); Brett Lance Johnson, Ft. Collins, CO (US); Vance Threatt, Austin, TX (US)

(73) Assignee: Advanced Micro Devices, Inc., Santa Clara, CA (US)

(21) Appl. No.: 18/542,136

(22) Filed: Dec. 15, 2023

(51) Int. Cl. G01R 31/3185; G11C 5/06

(52) U.S. Cl. CPC G01R 31/318505; G11C 5/063

(57) ABSTRACT

An exemplary apparatus for distributing die-specific signals across die stacks includes a die stack and a plurality of signals arranged in a sequence across the die stack. The plurality of signals shift positions in the sequence between a first die and a second die included in the die stack. Various other apparatuses, systems, and methods are also disclosed.

### BACKGROUND

Die stacks include multiple dies that are stacked together. In some examples, each die included in a die stack can implement a multiplexer to filter die-specific signals across the die stack. Unfortunately, such multiplexers can introduce undesirable characteristics like signal delay into the die stack. The instant disclosure, therefore, identifies and addresses a need for additional and improved apparatuses, systems, and methods that support distributing die-specific signals across die stacks.

### BRIEF DESCRIPTION OF THE DRAWINGS

The accompanying drawings illustrate a number of exemplary implementations and are a part of the specification. Together with the following description, these drawings demonstrate and explain various principles of the instant disclosure.

FIG. 1 is an illustration of an exemplary apparatus for distributing die-specific signals across die stacks according to one or more implementations of this disclosure.

FIG. 2 is an illustration of an exemplary apparatus for distributing die-specific signals across die stacks according to one or more implementations of this disclosure.

FIG. 3 is an illustration of an exemplary apparatus for distributing die-specific signals across die stacks according to one or more implementations of this disclosure.

FIG. 4 is an illustration of an exemplary implementation of die-specific signals being swizzled relative to a sequence arranged across a die stack according to one or more implementations of this disclosure.

FIG. 5 is an illustration of an exemplary system for distributing die-specific signals across die stacks according to one or more implementations of this disclosure.

FIG. 6 is an illustration of an exemplary system for distributing die-specific signals across die stacks according to one or more implementations of this disclosure.

FIG. 7 is a flowchart of an exemplary method for distributing die-specific signals across die stacks according to one or more implementations of this disclosure.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the instant disclosure covers all modifications, equivalents, and alternatives falling within the scope of the appended claims.

### DETAILED DESCRIPTION OF EXEMPLARY IMPLEMENTATIONS

The present disclosure describes various apparatuses, systems, and methods for distributing die-specific signals across die stacks. In some examples, a die stack can include and/or represent multiple dies that are stacked together. In one example, each die included in the die stack needs to filter and/or distinguish die-specific signals and/or data that are passed or carried across the die stack. In a traditional implementation of the die stack, each die can include and/or represent multiplexers for filtering and/or distinguishing the die-specific signals and/or data. Unfortunately, such multiplexers can introduce undesirable characteristics like signal delay into the die stack. To avoid and/or eliminate the need for such multiplexers, a die stack can implement a signal-swizzling technique and/or design that enables each die to filter and/or distinguish die-specific signals and/or data.

As a specific example, a die stack can be coupled to a base die that includes a clock source. In this example, the clock source can feed, deliver, and/or provide clock signals to each die included in the die stack. For the die stack to function properly and/or optimally, the clocks on each die can be synchronized with the clock source on the base die and/or with the other clocks on the other dies. The clock signals can vary slightly relative to one another to compensate and/or account for systematic offset caused by the different physical levels and/or heights of the individual dies included in the die stack. Unfortunately, if each die were to filter and/or distinguish the die-specific clock signals via a multiplexer, the delay introduced by the multiplexer would skew the corresponding clock signal, thereby potentially impairing the performance and/or functionality of the underlying device (e.g., difficulty in closing certain paths). Additionally or alternatively, the use of such multiplexers can increase the load on the driver of the clock source on the base die. Rather than relying on multiplexers for filtering and/or distinguishing the die-specific clock signals, the die stack can implement a signal-swizzling technique and/or design that enables each die to filter and/or distinguish die-specific signals and/or data.

As another example, a die stack can be coupled to a base die that facilitates and/or supports parallel scanning of the different dies included in the die stack. In this example, the base die can include and/or represent circuitry that generates and/or passes an input signal across the die stack. Each die included in the die stack can include and/or represent circuitry that receives the input signal and then generates a response based at least in part on that input signal. For the parallel scan to function properly and/or optimally, the responses generated by each die included in the die stack need to arrive at and/or reach the base die simultaneously. To accomplish such simultaneous arrival of those responses, the die stack can implement a signal-swizzling technique and/or design that enables each die to feed, deliver, and/or provide the corresponding response to the base die at the same position of a physical layout and/or sequence.

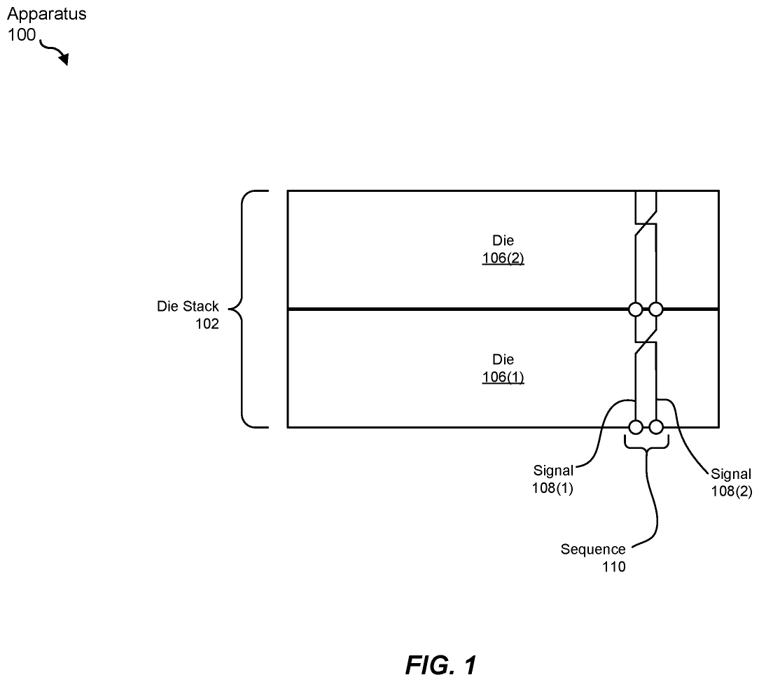

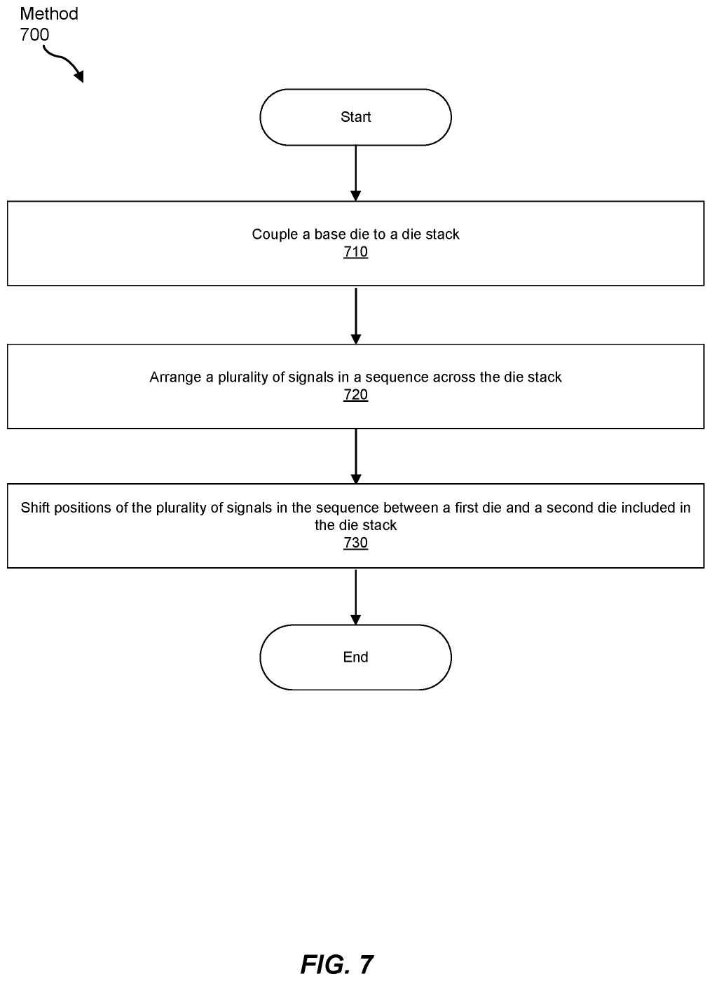

In some examples, the various apparatuses, systems, and/or methods described in the present disclosure can facilitate, support, and/or provide low insertion delays, low clock skews between base dies and each die included in die stacks, decreased loads on clock drivers included on base dies, and/or decreased power consumption by independently gating clock meshes implemented on the die stack such that only the active dies are clocked. The following will provide, with reference to FIGS. 1-6, detailed descriptions of exemplary apparatuses, systems, and/or corresponding implementations for distributing die-specific signals across die stacks. Detailed descriptions of an exemplary method for distributing die-specific signals across die stacks will be provided in connection with FIG. 7.

FIG. 1 illustrates an exemplary apparatus 100 that facilitates and/or supports distributing die-specific signals across die stacks. As illustrated in FIG. 1, exemplary apparatus 100 can include and/or represent a die stack 102 and signals 108(1) and 108(2). In some examples, die stack 102 can include and/or represent dies 106(1) and 106(2). In one example, signals 108(1) and 108(2) can be arranged in a sequence 110 across die stack 102. In this example, signals 108(1) and 108(2) can shift, rotate, and/or change positions in sequence 110 between die 106(1) and die 106(2).

In some examples, sequence 110 can constitute and/or represent a certain physical layout of signals 108(1) and 108(2) across die stack 102. For example, sequence 110 in FIG. 1 can include and/or represent two physical positions on each of dies 106(1) and 106(2). In one example, these positions can remain aligned and/or the same across each die included in die stack 102. In other words, the specific location and/or placement of sequence 110 can be consistent across dies 106(1) and 106(2).

In some examples, sequence 110 can constitute and/or represent physical positions of signals 108(1) and 108(2) within a certain area of each of dies 106(1) and 106(2). In one example, signal 108(1) can be shifted and/or moved in one direction (e.g., to the right) relative to sequence 110 between dies 106(1) and 106(2). In this example, signal 108(2) can be shifted and/or moved in the opposite direction (e.g., to the left) relative to sequence 110 between dies 106(1) and 106(2).

In some examples, dies 106(1) and 106(2) can each include and/or represent a small, diced piece of semiconductor material. In one example, dies 106(1) and 106(2) can each include and/or contain one or more circuits that consist of various electrical and/or electronic components (such as resistors, capacitors, transistors, memory units, processing devices, etc.). In this example, such circuits can be integrated into and/or created on dies 106(1) and 106(2) by a variety of fabrication processes. Examples of such fabrication processes include, without limitation, lamination, lithography, etching, deposition, chemical mechanical planarization, oxidation, ion implantation, photolithography, diffusion, combinations or variations of one or more of the same, and/or any other suitable fabrication processes.

In some examples, die stack 102 can include and/or represent a compilation and/or assortment of dies that are stacked on top of one another and/or physically or electrically coupled to one another. In one example, all or a portion of dies 106(1) and 106(2) can include and/or represent duplicates and/or copies of one another. For example, dies 106(1) and 106(2) can constitute and/or represent topologically or electrically identical copies of one another. Additionally or alternatively, dies 106(1) and 106(2) can be coupled, attached, and/or interfaced with one another via bonds, landing pads (e.g., hybrid-bond landing pads), through-silicon vias (TSVs), microbumps, and/or die-to-die interconnects.

In some examples, die stack 102 can be incorporated and/or packaged in or as an integrated circuit. For example, die stack 102 can constitute and/or represent a set of dies that include one or more memory and/or cache circuits. Additionally or alternatively, die stack 102 can constitute and/or represent a set of dies that include one or more processor and/or ASIC circuits. In one example, the integrated circuit can include and/or represent one or more semiconductor devices and/or components implemented or deployed as part of a computing system. Examples of such an integrated circuit include, without limitation, processing devices, microprocessors, microcontrollers, central processing units (CPUs), field-programmable gate arrays (FPGAs), application-specific integrated circuits (ASICs), systems on chips (SoCs), parallel accelerated processors, tensor cores, chiplets, memory devices, caches, portions of one or more of the same, variations or combinations of one or more of the same, and/or any other suitable integrated circuits.

In some examples, die stack 102 can be coupled, attached, and/or mounted to a substrate. In one example, all the dies included in die stack 102 can be stacked together using TSVs and then attached to the substrate as a stack. In a further example, a silicon interposer can be attached to the substrate first, after which die stack 102 and/or other components can be attached to the silicon interposer (in, e.g., a “2.5D” and/or “3D” package).

In some examples, signals 108(1) and 108(2) can each include and/or represent electrically conductive traces, paths, and/or connections that carry analog and/or digital data across die stack 102. In one example, signals 108(1) and 108(2) can be separated and/or electrically insulated from one another as necessary to form one or more circuits that incorporate electrical components and/or electronics across die stack 102. Signals 108(1) and 108(2) can each include and/or represent any type or form of electrically conductive material. Examples of such electrically conductive material include, without limitation, copper, aluminum, silver, gold, alloys of one or more of the same, combinations or variations of one or more of the same, and/or any other suitable materials.

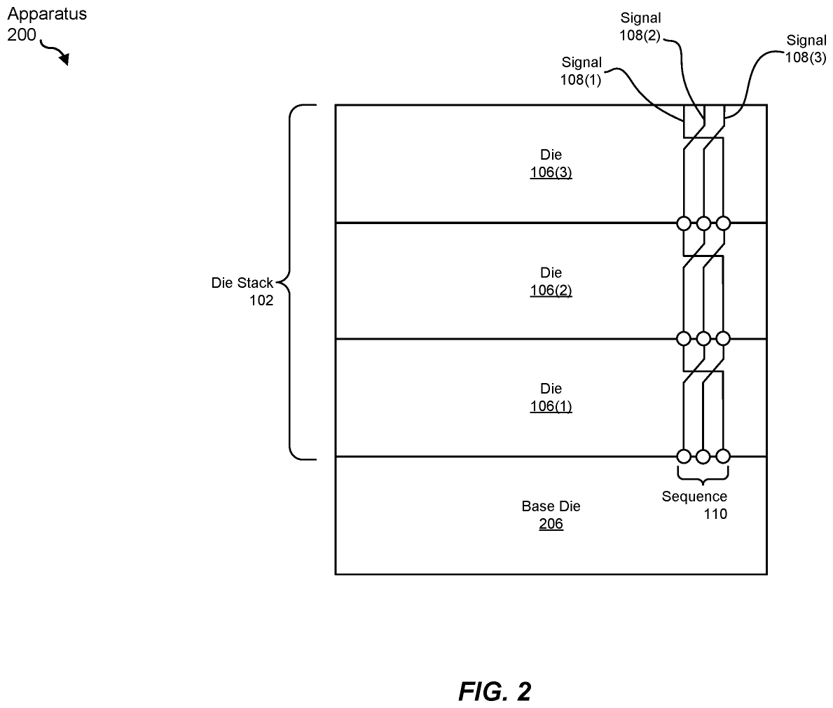

FIG. 2 illustrates an exemplary apparatus 200 for distributing die-specific signals across die stacks. In some examples, apparatus 200 can include and/or represent certain components and/or features that perform and/or provide functionalities that are similar and/or identical to those described above in connection with FIG. 1. As illustrated in FIG. 2, apparatus 200 can include and/or represent die stack 102, signals 108(1)-(3), and a base die 206. In one example, die stack 102 can include and/or represent dies 106(1)-(3). In this example, signals 108(1)-(3) can be arranged in sequence 110 across die stack 102.

In some examples, signals 108(1)-(3) can be swizzled relative to sequence 110 across die stack 102. For example, signals 108(1)-(3) can shift, rotate, and/or change positions in sequence 110 between die 106(1), die 106(2), and/or die 106(3). In one example, the number of dies included in die stack 102 can correspond to and/or match the number of signals involved in the swizzling relative to sequence 110 across die stack 102. For example, die stack 102 in FIG. 2 can include and/or represent three dies, and signals 108(1)-(3) can include and/or represent three signals.

In some examples, sequence 110 in FIG. 2 can include and/or represent a first position, a second position, and a third position that are aligned across die stack 102. In one example, signal 108(1) can be coupled and/or fixed to the first position on die 106(1). In this example, signal 108(2) can be coupled and/or fixed to the second position on die 106(1). Additionally or alternatively, signal 108(3) can be coupled and/or fixed to the third (and final) position on die 106(1).

In some examples, signal 108(1) can be shifted and/or moved to the second position on die 106(2). In one example, signal 108(2) can be shifted and/or moved to the third (and final) position on die 106(2). Additionally or alternatively, signal 108(3) can be shifted and/or moved to the first position on die 106(2).

In some examples, signal 108(1) can be shifted and/or moved to the third (and final) position on die 106(3). In one example, signal 108(2) can be shifted and/or moved to the first position on die 106(3). Additionally or alternatively, signal 108(3) can be shifted and/or moved to the second position on die 106(3).

In some examples, signals 108(1)-(3) can be arranged and/or patterned in the same way on both base die 206 and die 106(1). Additionally or alternatively, signals 108(1)-(3) can be arranged and/or patterned in the first, second, and third positions of sequence 110 on both base die 206 and die 106(1) and/or across the interface between base die 206 and die 106(1). In one example, sequence 110 can span and/or extend from base die 206 across die stack 102.

In some examples, base die 206 can include and/or represent a small, diced piece of semiconductor material. In one example, base die 206 can each include and/or contain one or more circuits that consist of various electrical and/or electronic components (such as resistors, capacitors, transistors, memory units, processing devices, etc.). For example, base die 206 can include and/or represent a compute die and/or core complex die (CCD) whose circuitry controls, directs, and/or manages die stack 102 in one way or another. In this example, such circuitry can be integrated into and/or created on base die 206 by a variety of fabrication processes. Examples of such fabrication processes include, without limitation, lamination, lithography, etching, deposition, chemical mechanical planarization, oxidation, ion implantation, photolithography, diffusion, combinations or variations of one or more of the same, and/or any other suitable fabrication processes.

In some examples, base die 206 can be physically and/or electrically coupled to die stack 102. For example, base die 206 can be directly attached to die 106(1) included in die stack 102. In one example, base die 206 can be topologically and/or electrically distinct from some or all of the dies included in die stack 102. Additionally or alternatively, base die 206 can be coupled, attached, and/or interfaced with die 106(1) via bonds, landing pads (e.g., hybrid-bond landing pads), TSVs, microbumps, and/or die-to-die interconnects. Base die 206 can also include and/or contain bonds, landing pads, TSVs, microbumps, and/or die-to-die interconnects on the side (e.g., the underside) opposite die 106(1).

In one example, all or a portion of dies 106(1)-(3) can include and/or represent duplicates and/or copies of one another. For example, dies 106(1)-(3) can constitute and/or represent topologically or electrically identical copies of one another. Additionally or alternatively, dies 106(1)-(3) can be coupled, attached, and/or interfaced with one another via bonds, landing pads (e.g., hybrid-bond landing pads), TSVs, microbumps, and/or die-to-die interconnects.

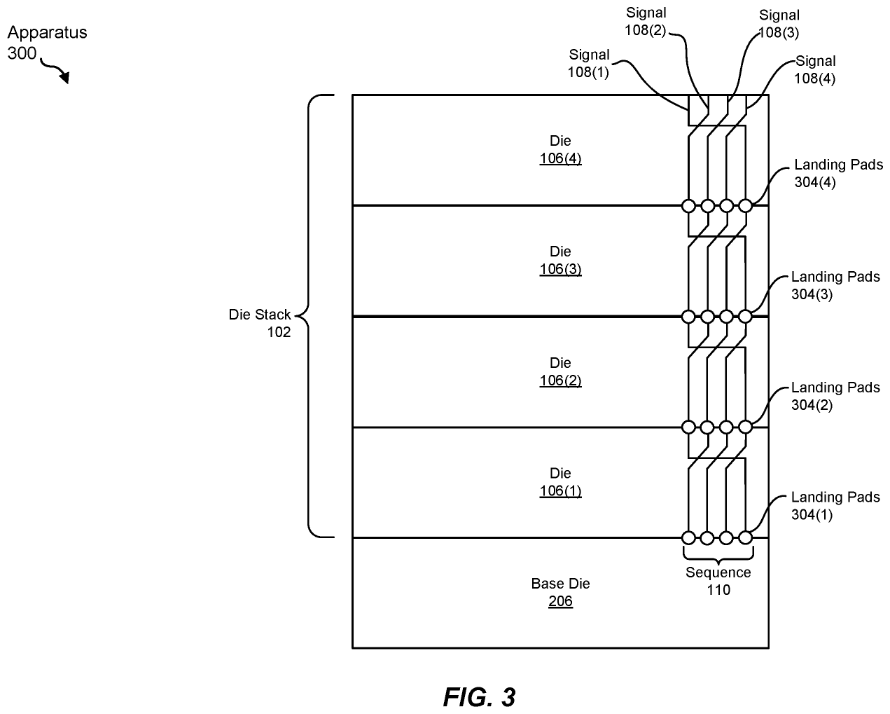

FIG. 3 illustrates an exemplary apparatus 300 for distributing die-specific signals across die stacks. In some examples, apparatus 300 can include and/or represent certain components and/or features that perform and/or provide functionalities that are similar and/or identical to those described above in connection with either of FIGS. 1 and 2. As illustrated in FIG. 3, apparatus 300 can include and/or represent die stack 102, signals 108(1)-(4), and base die 206. In one example, die stack 102 can include and/or represent dies 106(1)-(4). In this example, signals 108(1)-(4) can be arranged in sequence 110 across die stack 102.

In some examples, signals 108(1)-(4) can be swizzled relative to sequence 110 across die stack 102. For example, signals 108(1)-(4) can shift, rotate, and/or change positions in sequence 110 between die 106(1), die 106(2), die 106(3), and/or die 106(4). In one example, the number of dies included in die stack 102 can correspond to and/or match the number of signals involved in the swizzling relative to sequence 110 across die stack 102. For example, die stack 102 in FIG. 3 can include and/or represent four dies, and signals 108(1)-(4) can include and/or represent four signals.

In some examples, sequence 110 in FIG. 3 can include and/or represent a first position, a second position, a third position, and a fourth position that are aligned across die stack 102. In one example, signal 108(1) can be coupled and/or fixed to the first position on die 106(1). In this example, signal 108(2) can be coupled and/or fixed to the second position on die 106(1). Additionally or alternatively, signal 108(3) can be coupled and/or fixed to the third position on die 106(1). Finally, signal 108(4) can be coupled and/or fixed to the fourth (and final) position on die 106(1).

In some examples, signal 108(1) can be shifted and/or moved to the second position on die 106(2). In one example, signal 108(2) can be shifted and/or moved to the third position on die 106(2). Additionally or alternatively, signal 108(3) can be shifted and/or moved to the fourth (and final) position on die 106(2). Finally, signal 108(4) can be shifted and/or moved to the first position on die 106(2).

In some examples, signal 108(1) can be shifted and/or moved to the third position on die 106(3). In one example, signal 108(2) can be shifted and/or moved to the fourth (and final) position on die 106(3). Additionally or alternatively, signal 108(3) can be shifted and/or moved to the first position on die 106(3). Finally, signal 108(4) can be shifted and/or moved to the second position on die 106(3).

In some examples, signal 108(1) can be shifted and/or moved to the fourth (and final) position on die 106(4). In one example, signal 108(2) can be shifted and/or moved to the first position on die 106(4). Additionally or alternatively, signal 108(3) can be shifted and/or moved to the second position on die 106(4). Finally, signal 108(4) can be shifted and/or moved to the third position on die 106(4).

In one example, all or a portion of dies 106(1)-(4) can include and/or represent duplicates and/or copies of one another. For example, dies 106(1)-(4) can constitute and/or represent topologically or electrically identical copies of one another. Additionally or alternatively, dies 106(1)-(4) can be coupled, attached, and/or interfaced with one another via bonds, landing pads (e.g., hybrid-bond landing pads), TSVs, microbumps, and/or die-to-die interconnects. For example, apparatus 300 can also include and/or represent landing pads 304(1), 304(2), 304(3), and 304(4) that couple, bond, and/or attach signals 108(1)-(4) to certain positions in sequence 110 on each die included in die stack 102 and/or across the interfaces between one or more of base die 206 and/or dies 106(1)-(4). In this example, landing pads 304(1)-(4) can positioned, located, and/or placed to shoot and/or protrude out the back of dies 106(1)-(4), respectively.

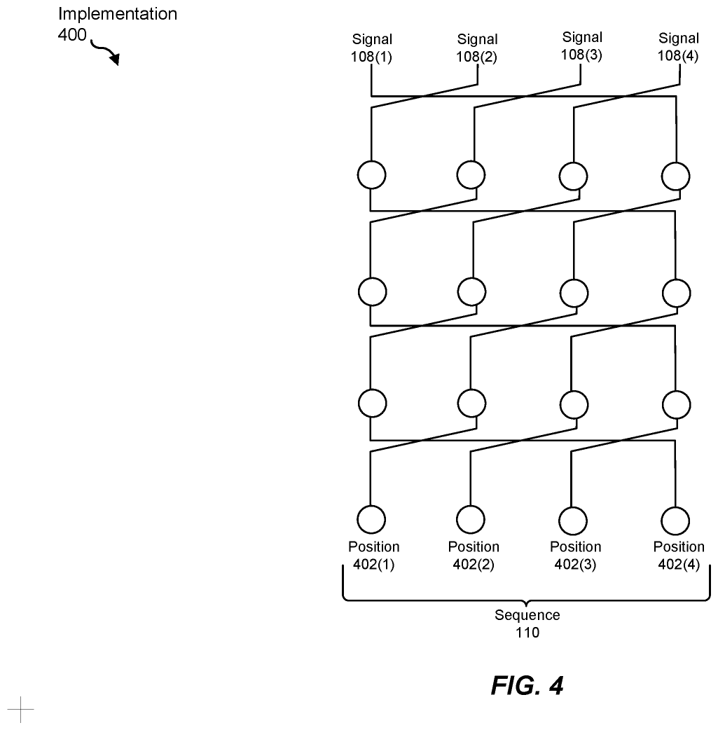

FIG. 4 illustrates an exemplary implementation 400 for distributing die-specific signals across die stacks. In some examples, implementation 400 can include and/or represent certain components and/or features that perform and/or provide functionalities that are similar and/or identical to those described above in connection with any of FIGS. 1-3. As illustrated in FIG. 4, implementation 400 can include and/or represent a certain pattern of signals 108(1)-(4) that are swizzled relative to sequence 110 across die stack 102. For example, sequence 110 can include and/or represent positions 402(1), 402(2), 402(3), and/or 402(4). In this example, signals 108(1)-(4) can be coupled and/or fixed to positions 402(1)-(4), respectively, on die 106(1), and signals 108(1)-(4) can be coupled and/or fixed to positions 402(2), 402(3), 402(4), and 402(1), respectively, on die 106(2). Additionally or alternatively, signals 108(1)-(4) can be coupled and/or fixed to positions 402(3), 402(4), 402(1), and 402(2), respectively, on die 106(3), and signals 108(1)-(4) can be coupled and/or fixed to positions 402(4), 402(1), 402(2), and 402(3), respectively, on die 106(4).

In some examples, the swizzling (e.g., shifting, rotating, and/or changing positions in sequence 110) can be performed and/or accomplished on the dies included in die stack 102. For example, after the landing pads on die 106(1), signals 108(1)-(4) can be swizzled relative to positions 402(1)-(4) on die 106(1) before reaching die 106(2) and/or the landing pads on die 106(2). In this example, after the landing pads on die 106(2), signals 108(1)-(4) can be further swizzled relative to positions 402(1)-(4) on die 106(2) before reaching die 106(3) and/or the landing pads on die 106(3). Additionally or alternatively, after the landing pads on die 106(3), signals 108(1)-(4) can be further swizzled relative to positions 402(1)-(4) on die 106(3) before reaching die 106(4) and/or the landing pads on die 106(4).

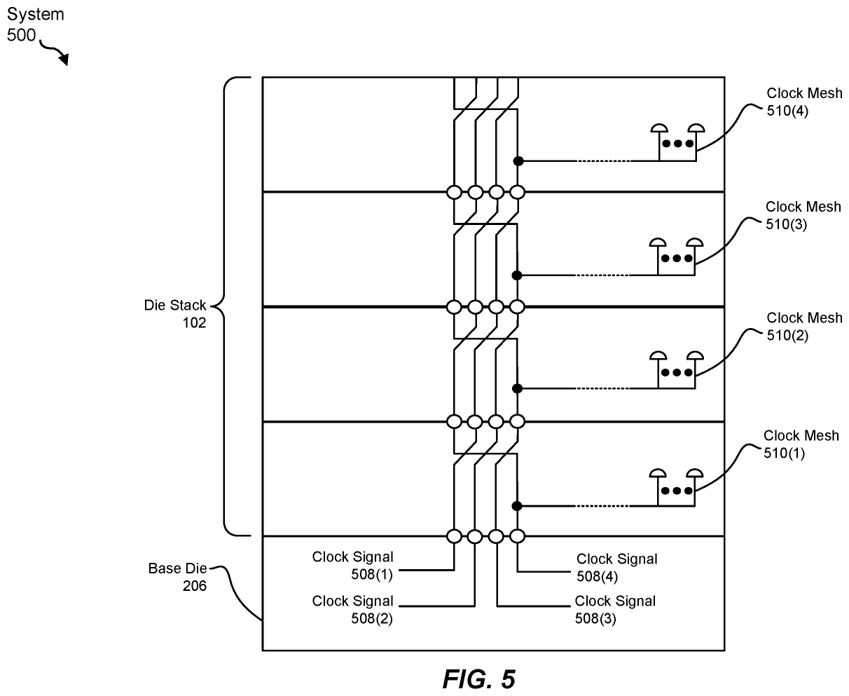

FIG. 5 illustrates an exemplary system 500 for distributing die-specific signals across die stacks. In some examples, system 500 can include and/or represent certain components and/or features that perform and/or provide functionalities that are similar and/or identical to those described above in connection with any of FIGS. 1-4. As illustrated in FIG. 5, system 500 can include and/or represent an implementation of apparatus 300 in which clock signals 508(1), 508(2), 508(3), and 508(4) are distributed throughout and/or across die stack 102 from base die 206. Accordingly, system 500 can alternatively include and/or represent an implementation of apparatus 300 in which multiple different clock signals are distributed throughout and/or across die stack 102 from base die 206.

In some examples, clock signals 508(1)-(4) can include and/or represent four instances of the same clock signal or four different clock signals that are independent of each other. In one example, die 106(1) can be configured to tap into and/or connect to clock signal 508(4) to obtain and/or draw the corresponding clock source. In this example, die 106(1) can also be configured to pass clock signal 508(4) to a clock mesh 510(1) for distribution throughout certain circuitry incorporated on die 106(1). Additionally or alternatively, die 106(2) can be configured to tap into and/or connect to clock signal 508(3) to obtain and/or draw the corresponding clock source. In this example, die 106(2) can also be configured to pass clock signal 508(3) to a clock mesh 510(2) for distribution throughout certain circuitry incorporated on die 106(2).

In one example, die 106(3) can be configured to tap into and/or connect to clock signal 508(2) to obtain and/or draw the corresponding clock source. In this example, die 106(3) can also be configured to pass clock signal 508(2) to a clock mesh 510(3) for distribution throughout certain circuitry incorporated on die 106(3). Additionally or alternatively, die 106(4) can be configured to tap into and/or connect to clock signal 508(1) to obtain and/or draw the corresponding clock source. In this example, die 106(4) can also be configured to pass clock signal 508(1) to a clock mesh 510(4) for distribution throughout certain circuitry incorporated on die 106(4).

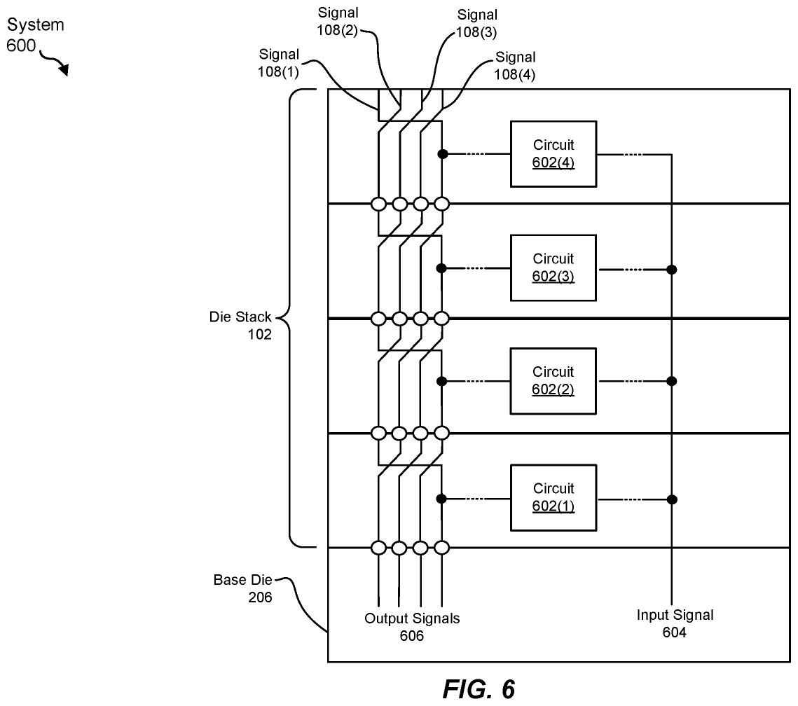

FIG. 6 illustrates an exemplary system 600 for distributing die-specific signals across die stacks. In some examples, system 600 can include and/or represent certain components and/or features that perform and/or provide functionalities that are similar and/or identical to those described above in connection with any of FIGS. 1-5. As illustrated in FIG. 6, system 600 can include and/or represent an implementation of apparatus 300 in which an input signal 604 is distributed throughout and/or across die stack 102 from base die 206. In one example, dies 106(1)-(4) can include and/or represent circuits 602(1), 602(2), 602(3), and 602(4), respectively. In this example, circuits 602(1)-(4) can be configured and/or programmed to perform one or more operations, measurements, and/or actions based at least in part on an input carried and/or distributed by input signal 604.

In some examples, circuits 602(1)-(4) can generate and/or compute a response and/or output based at least in part on the input. In one example, system 600 can include and/or represent a swizzled grouping of output signals 606 that descends across die stack 102 to base die 206. In this example, output signals 606 can carry and/or transport the responses and/or outputs generated or computed by circuits 602(1)-(4) across die stack 102 to base die 206.

In some examples, output signals 606 can include and/or represent signals 108(1)-(4). In one example, die 106(1) can be configured to tap into and/or connect to signal 108(4) to facilitate transmitting the corresponding response and/or output to base die 206 via signal 108(4). In this example, die 106(2) can be configured to tap into and/or connect to signal 108(3) to facilitate transmitting the corresponding response and/or output to base die 206 via signal 108(3). Additionally or alternatively, die 106(3) can be configured to tap into and/or connect to signal 108(2) to facilitate transmitting the corresponding response and/or output to base die 206 via signal 108(2). Finally, die 106(4) can be configured to tap into and/or connect to signal 108(1) to facilitate transmitting the corresponding response and/or output to base die 206 via signal 108(1).

In some examples, system 600 can facilitate, support, and/or implement parallel scanning across die stack 102 and/or circuits 602(1)-(4) based at least in part on input signal 604. In one example, the input carried and/or distributed by input signal 604 can include and/or represent test stimulus data, and the responses and/or outputs generated or computed by circuits 602(1)-(4) can collectively constitute and/or represent parallel data for testing, quality-control, and/or validation purposes. Accordingly, output signals 606 can carry and/or transport such parallel data from dies 106(1)-(4) to base die 206 in a swizzled pattern, configuration, and/or arrangement. In one example, circuitry incorporated on base die 206 can perform certain testing based at least in part on the parallel data. Additionally or alternatively, base die 206 can relay, pass, and/or distribute the parallel data to one or more components, devices, and/or systems external to base die 206 and/or die stack 102 for testing.

In some examples, the various devices and/or systems described in connection with FIGS. 1-6 can include and/or represent one or more additional circuits, components, and/or features that are not necessarily illustrated and/or labeled in FIGS. 1-6. For example, the apparatuses, implementations, and systems in FIG. 1-6 can also include and/or represent additional computing devices, analog and/or digital circuitry, digital logic, transmitters, receivers, transceivers, transistors, resistors, capacitors, diodes, multiplexers, inductors, switches, registers, flipflops, connections, traces, buses, semiconductor (e.g., silicon) devices and/or structures, processing devices, storage devices, circuit boards, packages, substrates, housings, combinations or variations of one or more of the same, and/or any other suitable components that facilitate and/or support distributing die-specific signals across die stacks. In certain implementations, one or more of these additional circuits, components, devices, and/or features can be inserted and/or applied between any of the existing circuits, components, and/or devices illustrated in FIGS. 1-6 consistent with the aims and/or objectives provided herein. Accordingly, the electrical and/or communicative couplings described with reference to FIGS. 1-6 can be direct connections with no intermediate components, devices, and/or nodes or indirect connections with one or more intermediate components, devices, and/or nodes.

In some examples, the phrase “to couple” and/or the term “coupling,” as used herein, can refer to a direct connection and/or an indirect connection. For example, a direct coupling between two components can constitute and/or represent a coupling in which those two components are directly connected to each other by a single node that provides electrical continuity from one of those two components to the other. In other words, the direct coupling can exclude and/or omit any additional components between those two components.

Additionally or alternatively, an indirect coupling between two components can constitute and/or represent a coupling in which those two components are indirectly connected to each other by multiple nodes that fail to provide electrical continuity from one of those two components to the other. In other words, the indirect coupling can include and/or incorporate at least one additional component between those two components.

FIG. 7 is a flow diagram of an exemplary method 700 for distributing die-specific signals across die stacks. In one example, the steps shown in FIG. 7 can be performed and/or executed during the manufacture, creation, and/or assembly of a base die and/or die stack. Additionally or alternatively, the steps shown in FIG. 7 can also incorporate and/or involve various sub-steps and/or variations consistent with the descriptions provided above in connection with FIGS. 1-6.

As illustrated in FIG. 7, exemplary method 700 includes and/or involves the step of coupling a base die to a die stack (710). Step 710 can be performed in a variety of ways, including any of those described above in connection with FIGS. 1-6. For example, a computing equipment manufacturer and/or subcontractor can couple, attach, and/or interface a base die to a die stack.

Exemplary method 700 also includes and/or involves the step of arranging a plurality of signals in a sequence across the die stack (720). Step 720 can be performed in a variety of ways, including any of those described above in connection with FIGS. 1-6. For example, a computing equipment manufacturer and/or subcontractor can arrange, dispose, and/or configure a plurality of signals in a sequence across the die stack.

Exemplary method 700 further includes the step of shifting positions of the plurality of signals in the sequence between a first die and a second die included in the die stack (730). Step 730 can be performed in a variety of ways, including any of those described above in connection with FIGS. 1-6. For example, a computing equipment manufacturer and/or subcontractor can shift, move, and/or change the positions of the plurality of signals in the sequence between a first die and a second die included in the die stack.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality. Furthermore, the various steps, events, and/or features performed by such components should be considered exemplary in nature since many alternatives and/or variations can be implemented to achieve the same functionality within the scope of this disclosure.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the instant disclosure. The implementations disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An apparatus comprising:
a die stack; and
a plurality of signals arranged in a sequence across the die stack, wherein the plurality of signals shift positions in the sequence between a first die and a second die included in the die stack.

2. The apparatus of claim 1, wherein the plurality of signals comprises:
a first signal that is shifted in one direction relative to the sequence between the first die and the second die; and
second and third signals that are shifted in another direction opposite the one direction between the first die and the second die.

3. The apparatus of claim 1, wherein:
the sequence comprises a first position, a second position, and a third position aligned across the die stack; and
the plurality of signals comprises:
a first signal coupled to the first position on the first die;
a second signal coupled to the second position on the first die; and
a third signal coupled to the third position on the first die.

4. The apparatus of claim 3, wherein:
the first signal is shifted to a final position in the sequence on the second die;
the second signal is shifted to the first position on the second die; and
the third signal is shifted to the second position on the second die.

5. The apparatus of claim 4, wherein the final position in the sequence is the third position.

6. The apparatus of claim 4, wherein the plurality of signals comprises a fourth signal that is coupled to a fourth position in the sequence on the first die and is shifted to the third position on the second die.

7. The apparatus of claim 6, wherein:
the first signal is shifted to the third position on a third die included in the die stack;
the second signal is shifted to the final position on the third die;
the third signal is shifted to the first position on the third die; and
the fourth signal is shifted to the second position on the third die.

8. The apparatus of claim 7, wherein:
the first signal is shifted to the second position on a fourth die included in the die stack;
the second signal is shifted to the third position on the fourth die;
the third signal is shifted to the final position on the fourth die; and
the fourth signal is shifted to the first position on the fourth die.

9. The apparatus of claim 8, wherein the first die, the second die, the third die, and the fourth die are duplicates of one another.

10. The apparatus of claim 2, wherein:
the sequence is arranged at a specific location relative to the first die; and
the sequence is arranged at the specific location relative to the second die.

11. The apparatus of claim 1, wherein the plurality of signals comprises multiple instances of a clock signal distributed across the die stack.

12. The apparatus of claim 1, further comprising a base die that is coupled to the die stack, wherein a number of dies included in the die stack corresponds to a number of signals included in the plurality of signals.

13. The apparatus of claim 12, further comprising an input signal that carries an input from the base die to each die included in the die stack, and wherein the plurality of signals carries parallel data from each die included in the die stack to the base die.

14. The apparatus of claim 13, wherein the input comprises test stimulus data, and the parallel data comprises a response to the input generated by each die included in the die stack.

15. A system comprising:
a base die;
a die stack coupled to the base die; and
a plurality of signals arranged in a sequence that spans from the base die across the die stack, wherein the plurality of signals shift positions in the sequence between each die included in the die stack.

16. The system of claim 15, wherein the plurality of signals comprises:
a first signal that is shifted in one direction relative to the sequence between a first die and a second die included in the die stack; and
second and third signals that are shifted in another direction opposite the one direction between the first die and the second die.

17. The system of claim 15, wherein:
the sequence comprises a first position, a second position, and a third position aligned across the die stack; and
the plurality of signals comprises:
a first signal coupled to the first position on the first die;
a second signal coupled to the second position on the first die; and
a third signal coupled to the third position on the first die.

18. The system of claim 17, wherein:
the first signal is shifted to a final position in the sequence on the second die;
the second signal is shifted to the first position on the second die; and
the third signal is shifted to the second position on the second die.

19. The system of claim 18, wherein the plurality of signals comprises a fourth signal that is coupled to a fourth position in the sequence on the first die and is shifted to the third position on the second die.

20. A method comprising:
coupling a base die to a die stack;
arranging a plurality of signals in a sequence across the die stack; and
shifting positions of the plurality of signals in the sequence between a first die and a second die included in the die stack.
